(19) United States
(12) Patent Application Publication
(10) Pub. No.: US 2018/0005872 A1
(43) Pub. Date: Jan. 4, 2018

(54) PREPARATION OF SILICON-GERMANIUM-ON-INSULATOR STRUCTURES

(71) Applicants: Shawn George THOMAS, St. Peters, MO (US); SunEdison Semiconductor Limited (UEN201334164H), Singapore (SG)

(72) Inventors: Shawn George Thomas, Chesterfield, MO (US); Gang Wang, Grover, MO (US)

(21) Appl. No.: 15/540,859

(22) PCT Filed: Dec. 29, 2015
(86) PCT No.: PCT/US2015/067816

§ 371 Date: Jun. 29, 2017

Related U.S. Application Data
(60) Provisional application No. 62/098,450, filed on Dec. 31, 2014.

(51) Int. Cl. H01L 21/762; H01L 21/768

(52) U.S. Cl. CPC H01L 21/76254; H01L 21/76829; H01L 21/76243; H01L 21/76262

(57) ABSTRACT

Donor structures having a germanium buffer layer for preparing silicon-germanium-on-insulator structures by layer transfer are disclosed. Bonded structures and methods for preparing silicon-germanium-on-insulator structures by a layer transfer method are also disclosed.

### CROSS-REFERENCE TO RELATED APPLICATION

This application claims the benefit of U.S. Provisional Patent Application No. 62/098,450, filed Dec. 31, 2014, which is incorporated herein by reference in its entirety.

### FIELD OF THE DISCLOSURE

The field of the disclosure relates to preparation of silicon-germanium-on-insulator structures and, in particular, methods that involve use of a germanium buffer layer and to donor structures and bonded structures used to prepare such silicon-germanium-on-insulator structures.

### BACKGROUND

Multi-layered structures comprising a device layer with a device quality surface, such as a silicon-geranium device layer, are useful for a number of different purposes. Silicon-germanium based devices may be characterized by enhanced electrical properties. Such silicon-germanium device layers may be fabricated on an insulator to reduce parasitic capacitances and improve isolation. Silicon-germanium-on-insulator (SGOI) structures can be used to produce a variety of devices including CMOS and MOSFET devices.

Multi-layered structures including donor structures used to produce SGOI structures by layer transfer may include multiple layers of material having differing coefficients of thermal expansion. During manufacture of such structures, however, the different rates of thermal expansion can create very large stresses in the multi-layered structures when they are heated, which can fracture the device layer or substrate. This places severe constraints on the maximum temperature that these dissimilar pairs can be exposed to during manufacture.

A continuing need exists for silicon-germanium-on-insulator structures having an improved device layer quality and for layer transfer methods for preparing such structures that are characterized by relatively low threading dislocations and low donor wafer bow.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to a multi-layered semiconductor donor structure having two major, generally parallel surfaces, one of which is a front surface and the other of which is a back surface. The donor structure comprises a single crystal silicon handle layer and a device layer comprising silicon and germanium. A relaxed buffer layer is disposed between the single crystal silicon handle layer and the device layer. The buffer layer comprises at least about 90 wt % germanium. The single crystal semiconductor handle layer and semiconductor buffer layer form a handle-buffer interface.

Another aspect of the present disclosure is directed to a method for preparing a multi-layered crystalline structure. Ions selected from the group consisting of hydrogen, helium and combinations thereof are implanted into a donor structure having a central axis and an implantation surface generally perpendicular to the central axis. The donor structure comprises a semiconductor device layer comprising silicon and germanium, a handle layer, and a relaxed germanium buffer layer which is positioned along the central axis of the donor structure between the device surface and the handle layer. The relaxed germanium buffer layer comprises at least about 90 wt % germanium. The ions are implanted into the donor structure through the implantation surface to an implantation depth sufficient to form in the implanted donor structure a damage layer which is generally perpendicular to the axis and located in the buffer layer and/or in the handle layer. The implanted donor structure is bonded to a second structure to form a bonded structure. The donor structure is cleaved along the damaged layer to form a multi-layered crystalline structure comprising the second structure, the device layer and residual material. The residual material comprises at least a portion of the buffer layer and optionally a portion of the handle layer. The residual material is removed from the multi-layered crystalline structure.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1A is a cross-sectional, schematic drawing of a donor structure for preparing a SiGe-on-insulator structure;

FIG. 1B is a cross-sectional, schematic drawing of a second structure, prior to bonding with the donor structure of FIG. 1A.

FIG. 2 is a cross-sectional, schematic drawing of a bonded structure, resulting from contacting a surface of the donor structure of FIG. 1A with the second structure of FIG. 1B;

FIG. 3 is a cross-sectional, schematic drawing showing separation of the bonded structure along the damage layer in the germanium buffer layer;

FIG. 4 is a cross-sectional, schematic drawing of the SiGe-on-insulator structure; and

FIG. 5 is a cross-sectional, schematic drawing of another embodiment of the donor structure having a passivation layer and an etch stop layer.

Corresponding reference characters indicate corresponding parts throughout the drawings.

### DETAILED DESCRIPTION

In accordance with the present disclosure, an improved process for producing a multi-layered crystalline structure and, in particular, a silicon-germanium-on-insulator structure (“SiGe-on-insulator” or “SGOI”) has been discovered. More specifically, it has been discovered that the use of a strain-relaxed germanium buffer layer in a donor structure may be used to transfer a high-quality silicon-germanium layer to produce a silicon-germanium-on-insulator structure. During or after layer transfer, the bonded structure is cleaved in the germanium buffer layer and residual material may be removed to produce a device-quality silicon-germanium layer.

Advantageously, the germanium buffer layer of the donor structure may include a reduced number of threading dislocations relative to conventional structures and the threading dislocations which are present may more readily glide and be annihilated during buffer layer growth and subsequent anneals. The high mobility of threading dislocations in the germanium buffer layer prevents dislocation pile-ups from forming in the device layer. Such dislocation pile-ups are associated with a high stress field which drives surface atom migration leading to large surface roughness and undulations. A high stress field may cause layer transfer failure and/or make the device layer susceptible to defect formation in device fabrication. High amounts of threading dislocations (e.g., dislocation density >10⁸ per cm²) and pile-ups may result in a stress field that scatters carriers which reduces carrier mobility and causes poor device performance.

Reducing the amount of dislocation pile-ups in the germanium buffer also reduces stress between the germanium buffer layer and the germanium-silicon device layer which reduces bow and deformation of the donor structure which allows for better device layer transfer. The lattice mismatch between the strain-relaxed germanium buffer layer and the silicon-germanium device layer creates tensile stress in the silicon-germanium device layer which promotes surface atom migration resulting in smoothing of the silicon-germanium device layer during growth. Dislocations that remain in the germanium buffer layer promote strain relaxation of the silicon-germanium device layer without creating dislocations in the device layer. Further, prior to silicon-germanium device layer growth, the germanium buffer layer may be sufficiently smoothed by use of a thermal anneal without use of a chemical-mechanical-polish as in conventional methods. Relatively thick germanium buffers (e.g., about 500 nm or more with about 5 μm or more or even 10 μm or more being preferred) may be used to achieve a low density of threading dislocations. Advantageously, the germanium buffer layer of the donor structure may be recycled multiple times.

### I. Formation of the Multi-Layered Crystalline Structure

The multi-layered crystalline structure of the present disclosure may be prepared by implanting ions into a donor structure comprising a semiconductor device layer comprising germanium and silicon, a handle layer and a germanium buffer layer, bonding the implanted donor structure to a second structure to form a bonded structure, cleaving the handle layer and a portion of the germanium buffer layer from the device layer which remains bonded to the second structure and optionally etching the residual germanium buffer layer from the device layer thereby exposing the device layer.

The donor structure provides the device layer for the final multi-layered crystalline structure. The other substrate will be referred to hereinafter as the “second structure.” The second structure may be comprised of single crystal silicon, sapphire, quartz crystal, glass, silicon carbide, silicon, gallium nitride, aluminum nitride, gallium aluminum nitride, gallium arsenic, indium gallium arsenic or any combination thereof.

The Si—Ge-on-insulator structure produced according to the present disclosure (including the donor and second structures used to produce such structures) may be any diameter suitable for use by those of skill in the art including, for example, about 200 mm, about 300 mm, greater than about 300 mm or even about 450 mm.

A. Donor Structure

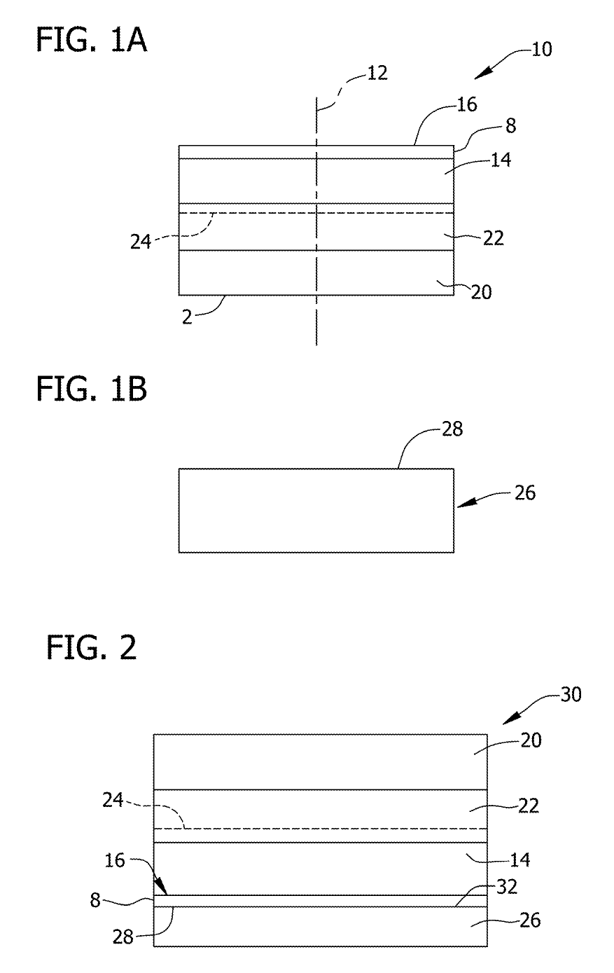

Referring now to FIG. 1A, the donor structure 10 comprises a central axis 12 and two major, generally parallel surfaces, one of which is a front surface 16 (also referred to herein as “implantation surface”) and the other of which is the back surface 2, both surfaces being generally perpendicular to the central axis 12. The donor structure 10 includes a silicon-germanium device layer 14, a handle layer 20 and a germanium buffer layer 22, which is positioned along the central axis 12 of the donor structure 10 between the device layer 14 and the handle layer 20. The handle layer 20 and germanium buffer layer 22 form a handle-buffer interface and the germanium buffer layer 22 and silicon-germanium device layer 14 form a buffer-device layer interface. The donor structure 10 may include an optional dielectric layer 8 at the surface of the donor structure.

The device layer 14 comprises silicon and germanium and, in some embodiments, contains silicon and germanium according to the formula:

Si₍₁₋ₓ₎Geₓ

wherein x is between about 0.5 and about 1.0. In some embodiments, x is between about 0.70 and about 0.85. The device layer 14 may contain at least about 95 wt % silicon and germanium (i.e., contain about 5 wt % or less of compounds other than silicon and germanium) or at least about 97.5 wt %, at least about 99 wt %, at least about 99.9 wt % silicon and germanium or even consist essentially of silicon and germanium (i.e., contain other compounds in only impurity amounts).

In general, the silicon-germanium device layer 14 has an average thickness which is suitable for use in the production of microelectronic or photovoltaic devices; however the device layer may have a thickness greater than those typically used without departing from the scope of the present disclosure. Generally, the device layer 14 has an average thickness of at least about 5 nm, typically at least about 8 nm and may have a thickness of from about 5 nm to about 300 nm.

The germanium buffer layer 22 comprises at least about 90 wt % germanium or, as in other embodiments, at least about 95 wt %, at least about 97.5 wt %, at least about 99 wt %, at least about 99.9 wt % germanium or consists essentially of germanium. In general, the germanium buffer layer 22 has an average thickness of at least about 500 nm or at least about 750 nm, at least about 1 μm, at least about 2 μm, at least about 3 μm or even at least about 4 μm (e.g., from about 500 nm to about 10 μm, from about 500 nm to about 5 μm, from about 750 nm to about 10 μm or from about 1 μm to about 5 μm).

The handle layer comprises single crystal silicon. Generally the handle layer comprises at least about 90 wt % silicon or, as in other embodiments, at least about 95 wt %, at least about 97.5 wt %, at least about 99 wt % or at least about 99.9 wt % silicon. In general, the handle layer 20 may have any thickness capable of providing sufficient structural integrity to allow delamination of the device layer 14 and at least a portion of the germanium buffer layer 22 and the handle layer 20 without departing from the scope of the present disclosure. In general, the handle layer 20 may have an average thickness of at least about 100 μm, typically at least about 200 μm and may have a thickness of from about 100 μm to about 900 μm or even from about 500 μm to about 800 μm.

In some embodiments, the donor structure 10 may further include a bonding layer, such as an oxide layer, deposited oxides, TEOS, CVD nitrides, or organic adhesives, on its surface prior to or after the implantation of ions into the donor structure 10 and/or prior to the bonding of the donor structure 10 to the second structure 26 (FIG. 1B). Alternatively or in addition, a bonding layer may be formed on the second structure 26 prior to bonding. The application of the bonding layer provides a bonding interface between the donor structure 10 and the second structure 26 so as to prevent the formation of interfacial gaps that may occur during direct bonding of the donor structure 10 and the second structure 26. While not required, when present, the bonding layer may have an average thickness of at least about 10 nm, and may have an average thickness of at least about 1 μm or at least about 3 μm or greater.

It should be noted that any technique generally known in the art may be used to form the donor structure 10. The relaxed germanium buffer layer 22 may be formed by epitaxy. Suitable epitaxial processes may involve contacting the surface of the single crystal substrate 20 with a germanium gas (GeH₄, Ge₂H₆ or their halides) at a temperature between about 300° C. to about 700° C. and a pressure between about 1 kPa to about 100 kPa. The germanium buffer layer 22 becomes relaxed upon generation of misfit dislocations at the buffer-handle layer interface. At the two ends of the misfit dislocation is a threading dislocation. Generally any germanium buffer layer 22 with a thickness of about 1 nm begins to relax without a thermal treatment. Buffer layers 22 with a thickness of at least about 5 nm (e.g., about 10 nm or more) may be fully relaxed without thermal treatment. X-ray diffraction (to determine the lattice constant) may be used to characterize the degree of strain relaxation in the germanium buffer layer 22. The lattice constant of the germanium buffer layer 22 may be compared with bulk germanium to determine the degree of strain relaxation.

After deposition, the strain-relaxed germanium buffer layer 22 (prior to any further anneal) may include a density of threading dislocations less than other conventional buffer layers. In some embodiments, the density of threading dislocations in the germanium buffer layer 22 of the donor structure 10 is less than about 1×10⁸ per cm², less than about 5×10⁷ per cm², less than about 1×10⁷ per cm², less than about 5×10⁶ per cm², less than about 1×10⁶ per cm², less than about 5×10⁵ per cm² or even less than about 1×10⁵ dislocations per cm².

After the germanium buffer layer 22 is deposited, the buffer 22 and substrate 20 are annealed to reduce the threading dislocations in the germanium buffer layer 22 and to smooth its surface. The anneal may be performed in a hydrogen, nitrogen and/or argon atmosphere and at a temperature of at least about 600° C. The anneal may be performed for at least about one second (e.g., at least about 5 seconds or at least about 10 seconds). Generally, anneals of about 30 seconds or less are sufficient to reduce threading dislocation and smooth the surface, however longer anneals may be used.

The silicon-germanium device layer 14 may be deposited by epitaxial deposition by use of a mixture of one or more silicon gases (SiH₄, Si₂H₆, Si₃H₈ or their halides) and one or more germanium gases (GeH₄, Ge₂H₆ or their halides) at a temperature between about 300° C. to about 700° C. and a pressure between 1 kPa to about 100 kPa. Generally, the silicon-germanium layer 14 is relatively uniform in the distribution of silicon and germanium throughout its thickness (e.g., the concentration (molar or weight concentration) of silicon and/or germanium does not vary by more than about 25% between the top and bottom of the layer 14 or no more than about 10%, no more than about 5% or no more than about 1% variance between the top and bottom of the layer 14).

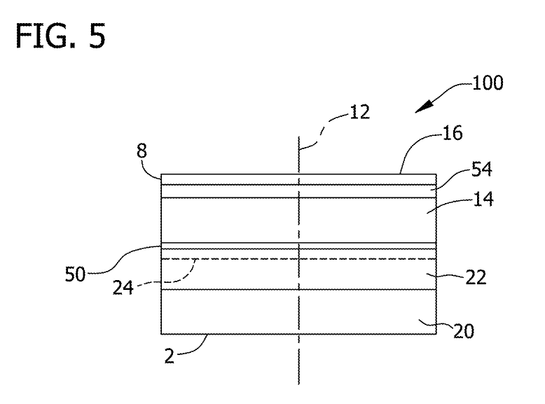

Another embodiment of the donor structure is shown in FIG. 5. The donor structure 100 includes an etch stop layer 50 disposed between the silicon-germanium device layer 14 and the germanium buffer layer 22. The buffer layer 22 and etch stop layer 50 form a buffer-etch stop interface and the etch-stop layer 50 and device layer 14 form a device-etch stop interface. The etch stop layer 50 may be composed of silicon (e.g., at least about 90 wt %, at least about 95 wt % or at least about 99 wt %) and may be deposited by epitaxy at a temperature between about 300° C. to about 600° C. and a pressure between about 1 kPa to about 100 kPa. The etch stop layer 50 may have an average thickness of at least about 0.5 nm or at least about 1 nm, at least about 5 nm or at least about 10 nm (e.g., from about 0.5 nm to about 20 nm). The etch stop layer 50 may be strained or relaxed. In some embodiments, the etch stop layer 50 is strained to prevent generation of additional defects, such as threading dislocations, which improves the silicon-germanium device layer 14 quality.

The donor structure 100 may also contain a silicon passivation layer 54 disposed on the silicon-germanium device layer 14. The passivation layer 54 acts to reduce device leakage and to enhance device performance in the resulting SiGe-on-insulator structure. The silicon passivation layer 54 may be may be composed of silicon (e.g., at least about 90 wt %, at least about 95 wt % or at least about 99 wt %) and may be deposited by epitaxy under similar conditions as the etch stop layer 50 described above. The passivation layer 54 may have a thickness of at least about 0.5 nm (e.g., about 0.5 nm to about 2 nm).

It should be noted that while the donor structure 100 is shown with both an etch stop layer 50 and a passivation layer 54, the structure may comprise an etch stop layer 50 without a passivation layer 54 or may comprise a passivation layer 54 without an etch stop layer 50.

In some embodiments, the surface of the germanium buffer layer 22 is smoothed before depositing the silicon-germanium device layer 14 (FIG. 1A) or the etch stop layer 50 (FIG. 5). The surface of the germanium buffer layer 22 may be smoothed by the thermal anneal described above. The anneal may reduce the surface roughness (RMS) of the buffer layer 22 to less than about 1 nm at a scan size of about 2 μm×about 2 μm or less than about 0.75 nm or even less than about 0.5 nm at a scan size of about 2 μm×about 2 μm (e.g., from about 0.1 nm to about 1 nm, from about 0.1 nm to about 0.75 nm, from about 0.25 nm to about 1 nm or from about 0.25 nm to about 0.75 nm at a scan size of about 2 μm×about 2 μm). Generally, the desired surface roughness (e.g., less than about 1 nm, less than about 0.75 nm or even less than about 0.5 nm) may be achieved without a polishing step (e.g., chemical-mechanical polishing step).

The donor structure may include a dielectric layer 8 disposed on the surface of the silicon-germanium device layer 14 (FIG. 1A) or on the surface of the passivation layer 54 (FIG. 5). The dielectric layer 8 may be composed of silicon dioxide or silicon nitride and may also act as the bonding layer described above. The dielectric layer 8 may be formed by thermally annealing the structure in an atmosphere containing oxygen at a temperature between about 700° C. and about 900° C. and a pressure from about 0.1 kPa and about 100 kPa. The dielectric layer 8 may have an average thickness between about 1 nm and about 100 nm.

It should be further noted that the ranges and minimum thickness values set forth above are not narrowly critical, so long as the thickness is sufficient to perform a transfer of the device layer to the second structure by any of the aforementioned processes.

Referring again to FIG. 1A, ions, such as hydrogen and/or helium ions, are implanted through the implantation surface 16 at a substantially uniform depth. In the exemplary embodiment, the ions are implanted through the implantation surface 16 and into the germanium buffer 22 to an implantation depth that is greater than the thickness of the device layer 14 and any additional optional layer such as a dielectric layer 8, passivation layer 54 (FIG. 5) or etch stop layer 50. In another embodiment, the ions may be implanted through the implantation surface 16 and into the handle layer 20. The ion implantation defines a damage layer 24 in the layer in which the ions are implanted. In the exemplary embodiment, as shown in FIG. 1A and FIG. 5, the ion implantation defines a damage layer 24 within the germanium buffer layer 22.

In general, ions are implanted to an average depth that is sufficient to ensure a satisfactory transfer of the device layer 14 upon a subsequent bonding and cleaving process. Preferably, the implantation depth is minimized to decrease the amount of germanium buffer layer 22 transferred with the device layer 14. In general, the ions are implanted to a depth of at least about 200 Å or even at least about 1 μm beneath the implantation surface depending on the thicknesses of the device layer 14. In some embodiments, the ions may be implanted to a depth of at least about 20 nm, typically at least about 90 nm, at least about 250 nm or even at least about 500 nm. It should be noted, however, that larger implantation depths may be used without departing from the scope of the present disclosure as they merely increase the amount of buffer layer 22 and/or handle layer 20 that will be removed after cleaving to reveal the device layer 14. As such, it may be preferable to implant the ions to a depth of from about 200 Å to about 1 μm or even from about 20 nm to about 500 nm.

Ion implantation may be achieved using means known in the art. For example, implantation may be achieved in a manner according to the process of U.S. Pat. No. 6,790,747, the entire contents of which are incorporated herein by reference for all relevant and consistent purposes. In some embodiments, an energy of, for example, at least about 10 keV, at least about 20 keV, at least about 80 keV, or at least about 120 keV may be used to implant hydrogen at a dosage of at least about 1×10¹⁶ ions/cm², at least about 2×10¹⁶ ions/cm², at least about 1×10¹⁷ ions/cm², or even at least about 2×10¹⁷ ions/cm². Typically, the concentration of hydrogen implanted may be from about 2×10¹⁶ ions/cm² to about 6×10¹⁶ ions/cm². It should be noted, that hydrogen may be implanted as H₂⁺ or alternatively as H⁺ without departing from the scope of the present disclosure.

In other embodiments, an energy of, for example, at least about 10 keV, at least about 20 keV, at least about 30 keV, at least about 50 keV, at least about 80 KeV or even at least about 120 keV may be used to implant helium at a dosage of at least about 5×10¹⁵ ions/cm², at least about 1×10¹⁶ ions/cm², at least about 5×10¹⁶ ions/cm², or even at least about 1×10¹⁷ ions/cm². Typically, the concentration of helium implanted may be from about 1×10¹⁶ ions/cm² to about 3×10¹⁶ ions/cm².

In other embodiments, both hydrogen and helium ions are implanted. It should be noted that the implantation of hydrogen and helium in combination may be done concurrently or sequentially with hydrogen being implanted prior to the helium or alternatively, with helium being implanted prior to the hydrogen. Preferably, the hydrogen and helium are implanted sequentially with the helium being implanted first using at least about 10 keV, at least about 20 keV, or at least about 30 keV, at least about 50 keV, at least about 80 KeV or even at least about 120 keV to implant helium at a dosage of at least about 5×10¹⁵ ions/cm², at least about 1×10¹⁶ ions/cm², at least about 5×10¹⁶ ions/cm², or even at least about 1×10¹⁷ ions/cm² and then implanting hydrogen at substantially the same depth as the helium using at least about 10 keV, at least about 20 keV, at least about 30 keV, at least about 50 keV, at least about 80 KeV or even at least about 120 keV to implant hydrogen at a dosage of at least about 5×10¹⁵ ions/cm², at least about 1×10¹⁶ ions/cm², at least about 5×10¹⁶ ions/cm², or even at least about 1×10¹⁷ ions/cm². In one embodiment, for example, about 1×10¹⁶ He⁺ ions/cm² are implanted using about 36 keV into the donor structure after which about 5×10¹⁵ H₂⁺ ions/cm² are implanted at about 48 keV or alternatively about 1×10¹⁶H⁺ ions/cm² are implanted at about 24 keV into the donor structure. The specific amount of energy required to perform the implantation of the ions into the donor structure depends on type and form of ion(s) selected, the crystallographic structure of the material through which and into which the ions are being implanted and the desired implantation depth. It should be noted that the implantation may be carried out at any temperature suitable for such implantation. Typically, however, the implantation may be carried out at room temperature. It should be further noted that in this regard, the implantation temperature referred to is the global temperature and that localized temperature spikes may occur at the actual site of the ion beam due to the nature of ion implantation.

After implantation is performed, the donor structure 10 may be thermally treated to begin the formation a cleave plane at the damage layer 24. For example, the donor structure may be thermally treated at a temperature of from about 150° C. to about 375° C. for a period of from about 1 hour to about 100 hours. In an alternative embodiment, as is described below, this thermal treatment may be combined with a thermal treatment performed after the bonding of the donor structure 10 to the second structure 26 so as to simultaneously strengthen the bond between the donor structure 10 and the second structure 26 and begin the formation of the cleave plane at the damage layer 24.

B. Second Structure

Referring now to FIG. 1B, the second structure 26 comprises either a single wafer or a multi-layered wafer having a bonding surface 28. In the exemplary embodiment, as is shown in FIG. 1B, the second structure 26 comprises a single substrate. The substrate may be comprised of a material selected from the group consisting of single crystal silicon, sapphire, quartz crystal, glass, silicon carbide, silicon, gallium nitride, aluminum nitride, gallium aluminum nitride or any combination thereof. In one preferred embodiment, the second structure 26 comprises a single crystal silicon wafer. The substrate 26 may have a thickness between about 200 μm and about 1500 μm or between about 500 μm and about 750 μm.

In other embodiments, the second structure includes a dielectric layer (not shown) disposed thereon. The dielectric layer may be composed of silicon dioxide or silicon nitride and may also act as a bonding layer to assist in bonding the donor structure 10 to the second structure 26. The dielectric layer may be formed as explained above in regard to the dielectric layer 8 of the donor structure 10. Typically, at least one of the donor structure 10 and the second structure 26 includes a dielectric layer. In some embodiments, a dielectric layer is formed on both the donor structure 10 and the second structure 26, i.e., the dielectric layers may act as bonding layers for layer transfer. After bonding, the two bonded dielectric layers combine to form the dielectric layer of the Si—Ge-on-insulator structure. The dielectric layer may be thermally grown as described above with regard to dielectric layer 8. Alternatively, it may be deposited by CVD (e.g., for silicon dioxide, silicon nitride), atomic layer deposition (e.g., for aluminum oxide, hafnium oxide, zirconium oxide) or molecular beam epitaxy (e.g., for niobium oxide, gadolinium oxide and other rare earth oxides).

C. Wafer Bonding and Transfer of the Device Layer

Once the donor structure 10 and the second structure 26 have been prepared or selected, forming the final multi-layered crystalline structure comprises transferring the silicon-germanium device layer 14 (or passivation layer 54 or bonding layer if used) of the donor structure 10 onto the second structure 26. Generally speaking, this transfer is achieved by contacting the implantation surface 16 to the bonding surface 28 of the second structure 26 in order to form a single, bonded structure 30 (FIG. 2) with a bond interface 32 between the two surfaces, and then cleaving or separating the bonded structure along the cleave plane formed along the damage layer 24.

Prior to bonding, the implantation surface 16 and/or the bonding surface 28 may optionally undergo cleaning, a brief etching, and/or planarization to prepare these surfaces for bonding, using techniques known in the art. Without being bound by a particular theory, it is generally believed that the quality of both surfaces prior to bonding will have a direct impact on the quality or strength of the resulting bond interface.

Alternatively or in addition to further conditioning the implantation surface 16 and/or the bonding surface 28, a bonding layer may be formed on the implantation surface and/or the bonding surface prior to bonding the donor structure 10 to the second structure 26. It should be noted that when forming a bonding layer on the donor structure 10, such formation may be performed prior to or after the implantation step. The bonding layer may comprise any material suitable for bonding the donor structure 10 to the second structure 26 including for example an oxide layer such as silicon dioxide, silicon nitride, deposited oxides, such as TEOS, and bonding adhesives. Without being bound by a particular theory, the inclusion of the bonding layer provides a bonding interface between the donor structure 10 and the second structure 26 so as to prevent the formation of interfacial gaps that may occur during direct bonding of the donor structure 10 and the second structure 26. The thermal oxide growth temperature may range from at least about 800° C. to about 1100° C. (and no more than about 943° C. if grown on the donor structure 10), and the thickness of the bonding layer typically ranges from about 10 nm to about 200 nm. The atmosphere under which the bonding layer is grown typically comprises oxygen, nitrogen, argon, and/or mixtures thereof for dry oxidations and water vapor for wet oxidations. CVD deposited oxides are typically deposited at low temperatures (i.e. from about 400° C. to about 600° C.). Further, some bonding adhesives may be applied at a thickness of at least 1 μm at room temperature, or slightly higher, and then baked or cured at temperatures up to approximately 200° C.

The roughness of the surface is one way by which the surface quality is quantitatively measured, with lower surface roughness values corresponding to a higher quality surface. Therefore, the implantation surface 16 of the donor structure 10 and/or the bonding surface 28 of the second structure 26 may undergo processing to reduce the surface roughness. For example, in one embodiment, the surface roughness is less than about 5 Å. This lowered RMS value can be achieved prior to bonding by cleaning and/or planarization. Cleaning may be carried out according to a wet chemical cleaning procedure, such as a hydrophilic surface preparation process. One common hydrophilic surface preparation process is a RCA SC1 clean process, wherein the surfaces are contacted with a solution containing ammonium hydroxide, hydrogen peroxide, and water at a ratio of, for example, 1:4:20 at about 60° C. for about 10 minutes, followed by a deionized water rinse and spin dry. Planarization may be carried out using a chemical mechanical polishing (CMP) technique. Further, one or both of the surfaces may be subjected to a plasma activation to increase the resulting bond strength before, after, or instead of a wet cleaning process. The plasma environment may include, for example, oxygen, ammonia, argon, nitrogen, diborane, or phosphine. In one preferred embodiment, the plasma activation environment is selected from the group consisting of nitrogen, oxygen, and combinations thereof.

Referring now to FIG. 2, the donor structure 10 is bonded to the second structure 26 by bringing the implantation surface 16 of the donor structure 10 and the bonding surface 28 of the second structure 26 together to form a bond interface 32. Generally speaking, wafer bonding may be achieved using essentially any technique known in the art, provided the energy employed to achieve formation of the bond interface is sufficient to ensure the integrity of the bond interface is sustained during subsequent processing, such as layer transfer by mechanical cleaving or thermal separation. Typically, however, wafer bonding is achieved by contacting the implantation surface 16 of the donor structure 10 and the bonding surface 28 of the second structure 26 at room temperature, followed by a low temperature anneal for a period of time sufficient to produce a bond interface having a bond strength greater than about 500 mJ/m², about 750 mJ/m², about 1000 mJ/m², or more. To achieve such bond strength values, typically heating takes place at temperatures of at least about 200° C., at least about 300° C., at least about 400° C., or even about 500° C. or more for a period of time of at least about 5 minutes, about 30 minutes, about 60 minutes, or even about 300 minutes or more. As noted above, this low temperature thermal anneal may be performed in addition to, or in place of, the thermal treatment of the donor structure 10 prior to bonding, which is described above. In an embodiment wherein the donor structure 10 is not thermally annealed prior to bonding, the low temperature thermal anneal of the bonded structure 30 facilitates both the strengthening of the bond interface as well as the formation of the cleave plane that is located along the damage layer 24.

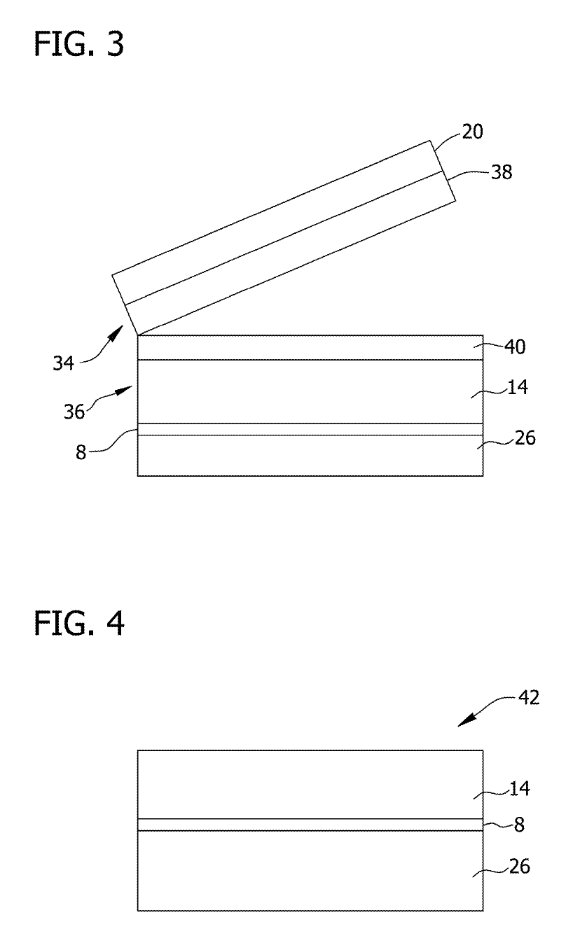

Referring now to FIG. 3, after the bond interface 32 has been formed, the resulting bonded structure 30 is subjected to conditions sufficient to induce a fracture along the damage layer 24 within the germanium buffer layer 22 or handle layer 20. Generally speaking, this fracture may be achieved using techniques known in the art, such as by a mechanical or thermal cleave. Typically, however, fracturing is achieved by annealing the bonded structure 30 at an elevated temperature for a period of time to induce fracture. For example, the annealing temperature may be at least about 200° C., at least about 250° C. or higher. In some embodiments, the anneal may even be carried out at temperatures of at least about 350° C., about 450° C., about 550° C., about 650° C., or even about 750° C., typically at temperatures of from about 200° C. to about 750° C., and more typically from about 200° C. to about 400° C. It should be noted, however, that because of the differing coefficients of thermal expansion of the various material involved, it is often preferable to carry out the aforementioned anneal at lower temperatures. As such, the anneal may be preferably carried out using an annealing temperature of from about 200° C. to about 300° C. The anneal is performed over a time period of at least about 5 minutes, about 30 minutes, about 60 minutes, or even about 300 minutes. Higher annealing temperatures will require shorter anneal times, and vice versa. The annealing step can be conducted in an ambient or inert atmosphere, e.g., argon or nitrogen.

In one preferred embodiment, the separation (i.e., fracturing the structure along the damage layer 24 within the germanium buffer layer 22 or handle layer 20) includes the application of mechanical force, either alone or in addition to the annealing process. The actual means of applying such a mechanical force is not critical to this disclosure; i.e., any known method of applying a mechanical force to induce separation in a semiconductor structure may be employed, so long as substantial damage to the device layer 14 is avoided.

Referring again to FIG. 3, two structures 34, 36 are formed upon separation. If the separation of the bonded structure 30 (FIG. 2) occurs along the damage layer 24 in the germanium buffer layer 22, and the cleave plane does not coincide with the bond interface 32, but rather is present in the germanium buffer layer 22, a portion of the germanium buffer layer 22 is part of both structures. In the exemplary embodiment, structure 34 comprises the handle layer 20 and some portion 38 of the germanium buffer layer 22. Structure 36 comprises the second structure 26, the dielectric layer 8, the silicon-germanium layer 14 and a residual portion 40 of the germanium buffer layer 22 on the surface thereof. In an alternative embodiment, wherein the ions are implanted to a depth so as to form the damage layer completely within the handle layer 20, structure 34 comprises the a portion of the handle layer and structure 36 comprises the second structure 26, dielectric layer 8, silicon-germanium device layer 14, germanium buffer layer 22 and the residual portion of the handle layer 20.

When present, the residual portion 40 of the germanium buffer layer 22 has a thickness that is approximately equivalent to the depth at which ions were implanted into the germanium buffer layer 22. Accordingly, this thickness is typically greater than about 10 nm. For example, in some instances the residual portion 40 may optionally be at least about 20 nm, about 50 nm, about 75 nm, about 100 nm, about 200 nm thick or more. Preferably, the thickness is sufficient to avoid damage to the silicon-germanium device layer 14 upon separation; for example, in one preferred embodiment, the residual portion is between about 20 nm to about 200 nm thick.

The structure 34 may be recycled for use as a donor structure 1A to produce additional SiGe-on-insulator structures. The structure 34 may be smoothed and a silicon-germanium device layer 14 and dielectric layer 8 may be deposited to form the donor structure 10 (FIG. 1A) for further processing.

II. Finishing the Multi-Layered Crystalline Structure after Layer Transfer

Referring to FIGS. 3 and 4, after the silicon-germanium device layer 14 and at least a portion of the germanium buffer layer 22 have been transferred to the second structure 26 to form bonded structure 36, bonded structure 36 is subjected to additional processing to produce a multi-layered crystalline structure having desirable features for device fabrication thereon. For example, the bonded structure 36 may be subjected to one or more processing steps in order to remove the residual germanium buffer layer 40. Although essentially any technique known in the art may be used, the residual portion 40 is preferably removed via etching. The etching composition may be selected according to various factors, including the composition of the residual portion 40 of the germanium buffer layer 22 and the selectivity of the etchant. In one embodiment, the entire residual portion 40 of the germanium buffer layer 22 is removed via a wet etching process using an etchant comprising NH₄OH, H₂O₂ and H₂O. This etchant is generally known to those skilled in the art and is commonly referred to as an “SC1” solution. Such an etching process is typically carried out at a temperature of from about 50° C. to about 80° C., with the time period of such an etch depending on the thickness of the layer to be removed, the exact composition of the SC1 composition, and the temperature under which the etch is performed.

As shown in FIG. 4, the final multi-layered crystalline structure 42 comprises the second structure 26, dielectric layer 8 and the silicon-germanium device layer 14.

In this regard, the donor structure 100 (FIG. 5) may be bonded to the second structure 26 and processed as described above with reference to the donor structure 10 (FIG. 1A). After cleaving along the damage layer 24, the residual germanium buffer layer 40 may be removed by etching. The etch stop layer 50 acts to limit the etch and prevent the silicon-germanium device layer 14 from being etched. The etch stop layer 50 may be removed by either a dry etch as disclosed by Oehrlein et al. in J. Electrochem. Soc., vol. 138(5) , p. 1443-1452 (1991) or a wet etch as disclosed by Loup et al. in ECS Trans. vol. 58(6), p. 47-55 (2013), both of which are incorporated herein by reference for all relevant and consistent purposes.

### III. Multi-Layered Crystalline Structure

The multi-layered crystalline structure 42 prepared in accordance with the present disclosure may have a substantially uniform thickness ranging from about 300 μm to about 800 μm. Preferably, in these or other embodiments, the device layer 14 has a thickness of from about 5 nm to about 200 nm, the dielectric layer 8 has a thickness of from about 10 nm to about 3000 nm and the second structure 26 has a thickness of from about 300 μm to about 800 μm.

Multi-layered crystalline structures manufactured according to this disclosure may be used in various technologies. For example, the multi-layered crystalline structures of this disclosure are suitable for use in the manufacture of a multi-layered microelectronic or nanoelectronic device comprising a microelectronic or nanoelectronic component and the multi-layered crystalline structure of the instant disclosure. Suitable devices include, but are not limited to logic CMOS devices.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a”, “an”, “the” and “said” are intended to mean that there are one or more of the elements. The terms “comprising,” “including,” “containing” and “having” are intended to be inclusive and mean that there may be additional elements other than the listed elements. The use of terms indicating a particular orientation (e.g., “top”, “bottom”, “side”, etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

1. A multi-layered semiconductor donor structure having two major, generally parallel surfaces, one of which is a front surface and the other of which is a back surface, the donor structure comprising:
a single crystal silicon handle layer;
a device layer comprising silicon and germanium;
a relaxed germanium buffer layer disposed between the single crystal silicon handle layer and the device layer, the buffer layer comprising at least about 90 wt % germanium, the single crystal handle layer and relaxed buffer layer forming a handle-buffer interface.

2. The multi-layered semiconductor donor structure as set forth in claim 1 wherein the device layer and the germanium buffer layer form a buffer-device layer interface.

3. The multi-layered semiconductor donor structure as set forth in claim 1 further comprising an etch-stop layer disposed between the buffer layer and the device layer.

4. The multi-layered semiconductor donor structure as set forth in claim 3 wherein the buffer layer and etch stop layer form a buffer-etch stop interface and wherein the device layer and etch stop layer form a device-etch stop interface.

5. The multi-layered semiconductor donor structure as set forth in claim 1 wherein the germanium buffer layer comprises at least about 95 wt % germanium.

6. The multi-layered semiconductor donor structure as set forth in claim 1 consisting essentially of the handle layer, the germanium buffer layer, the device layer, an optional etch stop layer, an optional passivation layer disposed on the device layer and an optional dielectric layer disposed on the device layer.

7. (canceled)

8. The multi-layered semiconductor donor structure as set forth in claim 1 wherein the device layer comprises silicon and germanium according to the formula:
Si₍₁₋ₓ₎Geₓ
wherein x is between about 0.5 and about 1.0.

9. The multi-layered semiconductor donor structure as set forth in claim 1 wherein the concentration of silicon and the concentration of germanium in the device layer does not vary by more than about 25%.

10. A bonded structure for preparing a multi-layered crystalline structure, the bonded structure comprising:
the donor structure of claim 1; and
a second structure bonded to the donor structure.

11. The bonded structure as set forth in claim 10 wherein the bonded structure comprises a central axis and a damage layer generally perpendicular to the central axis and located in the buffer layer.

12. (canceled)

13. A method for preparing a multi-layered crystalline structure, the method comprising:
implanting ions selected from the group consisting of hydrogen, helium and combinations thereof into a donor structure having a central axis and an implantation surface generally perpendicular to the central axis, wherein the donor structure comprises a semiconductor device layer comprising silicon and germanium, a handle layer, and a relaxed germanium buffer layer which is positioned along the central axis of the donor structure between the device surface and the handle layer, the relaxed germanium buffer layer comprising at least about 90 wt % germanium, wherein the ions are implanted into the donor structure through the implantation surface to an implantation depth sufficient to form in the implanted donor structure a damage layer which is generally perpendicular to the axis and located in the buffer layer and/or in the handle layer;
bonding the implanted donor structure to a second structure to form a bonded structure;
cleaving the donor structure along the damaged layer to form a multi-layered crystalline structure comprising the second structure, the device layer and residual material, the residual material comprising at least a portion of the buffer layer and optionally a portion of the handle layer; and,
removing the residual material from the multi-layered crystalline structure.

14. The method as set forth in claim 13 wherein the bonded structure includes a dielectric layer disposed between the second structure and the semiconductor device layer.

15. (canceled)

16. The method as set forth in claim 13 wherein the handle layer is a single crystal silicon substrate.

17. The method as set forth in claim 13 wherein the semiconductor device layer and the germanium buffer layer form a buffer-device layer interface.

18. The method as set forth in claim 13 wherein the donor structure comprises an etch-stop layer disposed between the buffer layer and the device layer.

19. (canceled)

20. The method as set forth in claim 13 wherein the donor structure is prepared by:
forming a relaxed germanium buffer layer on a front surface of a handle substrate; and
forming the semiconductor device layer comprising silicon and germanium on the germanium buffer layer.

21. The method as set forth in claim 20 comprising thermally annealing the handle substrate and germanium buffer layer prior to forming the semiconductor device layer to reduce threading dislocations in the germanium buffer layer and to reduce the surface roughness of the germanium buffer layer, the surface roughness of the germanium buffer layer being reduced to less than about 1 nm without chemical-mechanical polishing.

22. (canceled)

23. The method as set forth in claim 13 wherein the handle layer and buffer layer form a handle-buffer interface.

24-27. (canceled)

28. The method as set forth in claim 13 wherein the second structure comprises a substrate of single crystal silicon, sapphire, quartz crystal, glass, silicon carbide, silicon, gallium nitride, aluminum nitride, gallium aluminum nitride, or any combination thereof, the second structure comprising a dielectric layer disposed on the substrate, the implanted donor structure being bonded to the dielectric layer.

29-33. (canceled)

34. The method as set forth in claim 13 wherein cleaving the donor structure comprises separating the handle layer and a portion of the germanium buffer layer from the multi-layered structure, the handle layer and germanium buffer layer being reused to produce a second donor structure for preparing an additional multi-layered crystalline structure.
